(19) United States
(12) Patent Application Publication
(10) Pub. No.: US 2009/0274255 A1
(43) Pub. Date: Nov. 5, 2009

(54) METHOD AND APPARATUS FOR STABILIZING CLOCK

(75) Inventor: Bo Li, Shenzhen (CN)

Correspondence Address: Huawei Technologies Co., Ltd.;c/o Darby & Darby P.C., P.O. Box 770, Church Street Station, New York, NY, 10008-0770, US

(73) Assignee: Huawei Technologies Co., Ltd., Shenzhen (CN)

(21) Appl. No.: 12/424,963

(22) Filed: Apr. 16, 2009

(30) Foreign Application Priority Data
May 4, 2008 (CN) 200810093890.X

(51) Int. Cl. H03D 3/24

(52) U.S. Cl. 375/376

(57) ABSTRACT

A method and an apparatus for stabilizing a clock are provided. The apparatus for stabilizing a clock includes: a phase locked loop (PLL) module, configured to receive a filtered phase difference signal from a digital filtering module and output an output clock; a phase discrimination module, configured to receive an output feedback clock, and generate a phase difference signal reflecting a phase difference between the output feedback clock and the input clock; the digital filtering module, configured to receive the phase difference signal from the phase discrimination module, and generate the filtered phase difference signal after filtering the phase difference signal, then send the filtered phase difference signal to the PLL module. A division ratio of the PLL module is adjusted according to the filtered phase difference signal till the phase difference between the input clock and the output feedback clock maintains a stable state.

### CROSS-REFERENCE TO RELATED APPLICATION

This application claims priority to Chinese Patent Application No. 200810093890.X, filed 2008-05-04, entitled “Method and Apparatus for Stabilizing Clock”, commonly assigned, incorporated by reference herein for all purposes.

### BACKGROUND OF THE INVENTION

1. Field of the Invention

The present invention relates to the field of electronic information technology, and more particularly, to a method and an apparatus for stabilizing a clock.

2. Background of the Invention

Clock generation circuits are needed in various electronic products. For example, in a chip system, an independent oscillation circuit provides continuous pulse signals for the whole chip system, thereby satisfying the cooperation requirements for each part of the chip system. Such stable pulse signals are clock signals of the system. The clock may be generated in various different ways, for example, obtaining a clock of a frequency from a clock of another frequency, or obtaining a clock with a better performance from a clock with a poorer performance. As the progress of the integrated circuit (IC) design technology, it has an increasingly high requirement on the integration degree of the clock generation circuit, as well as the performance of the clock output by the circuit.

In the related art, the following two clock generation circuits are mainly adopted.

A phase locked loop (PLL) module in the related art is a clock generation circuit that has been widely applied in one related art, which generates a clock through an analog circuit. A phase and frequency detector (PFD) is adapted to compare an input clock with a feedback clock in the frequency and phase, and if the two clocks have different frequencies or phases, the PFD outputs a signal for reflecting the difference between the input clock and the feedback clock. A low pass filter (LPF) is adapted to filter out high frequency components in the signal output by the PFD, and transmits the filtered signal to a voltage controlled oscillator (VCO). The VCO changes the frequency of the output clock according to the change of the input control signal. The feedback clock is obtained from the output clock through a frequency division process. When the loop is locked, the input clock and the feedback clock have the same frequency and the same phase, and the frequency relation between the output clock and the feedback clock is determined by a division ratio of a divider (DIV), thereby determining the frequency relation between the output clock and the input clock. If the DIV has a division ratio of K, fₒᵤₜ=fᵢₙ×K. That is to say, when two input signals of the PFD, i.e., the input clock and a feedback of the output clock, are the same, no signal is output by the PFD, and at this time, the PLL enters a stable state.

II. A direct digital frequency synthesis (DDS) can realize a function of adjusting a frequency of an output clock by changing the numbers in another related art, thereby generating a clock by means of a digital circuit. The DDS generally includes a phase accumulator (phase accu), a phase to amplitude converting circuit (phase to amp), a digital to analog converter (DAC), a filter, and a comparator (CMP). Since the DDS controls the frequency through a digital circuit, it can be easily applied together with a digital signal processor (DSP). With respect to the LPF (for example, the LPF in the PLL module), the DSP can more easily realize the low pass filtering property with a low bandwidth. The DSP compares an input clock with an output clock of the DDS and performs a digital filtering process, so as to control the DDS, thereby generating a clock with a desired frequency.

### SUMMARY OF THE INVENTION

An apparatus for stabilizing a clock includes a phase locked loop (PLL) module, a phase discrimination module and a digital filtering module. The PLL module is configured to receive a filtered phase difference signal from the digital filtering module and output an output clock. The phase discrimination module is configured to receive an output feedback clock and an input clock, and generate a phase difference signal reflecting a phase difference between the output feedback clock and the input clock. An output clock is taken as the output feedback clock. The digital filtering module is configured to receive the phase difference signal from the phase discrimination module, and generate the filtered phase difference signal after filtering the phase difference signal, then send the filtered phase difference signal to the PLL module. Wherein a division ratio of the PLL module is adjusted according to the filtered phase difference signal till the phase difference between the input clock and the output feedback clock maintains a stable state.

An method for stabilizing a clock includes: obtaining a signal for reflecting a phase difference between an input clock and an output feedback clock according to the input clock and the output feedback clock of the output clock; generating a filtered signal after filtering the signal; adjusting a division ratio of a PLL module according to the filtered signal to influence the output clock generated by the PLL module. Wherein an output clock is taken as the output feedback clock.

### BRIEF DESCRIPTION OF THE DRAWINGS

FIG. 1 is a schematic diagram of an apparatus for stabilizing a clock according to an embodiment of the present invention;

FIG. 2 is a schematic view of an apparatus for stabilizing a clock according to another embodiment of the present invention;

FIG. 3 is a schematic view of an apparatus for stabilizing a clock according to another embodiment of the present invention;

FIG. 4 is a schematic view of an apparatus for stabilizing a clock according to another embodiment of the present invention; and

FIG. 5 is a flow chart of a method for stabilizing a clock according to an embodiment of the present invention.

### DETAILED DESCRIPTION OF THE EMBODIMENTS

The specific embodiments of the present invention are described below in detail with reference to the drawings.

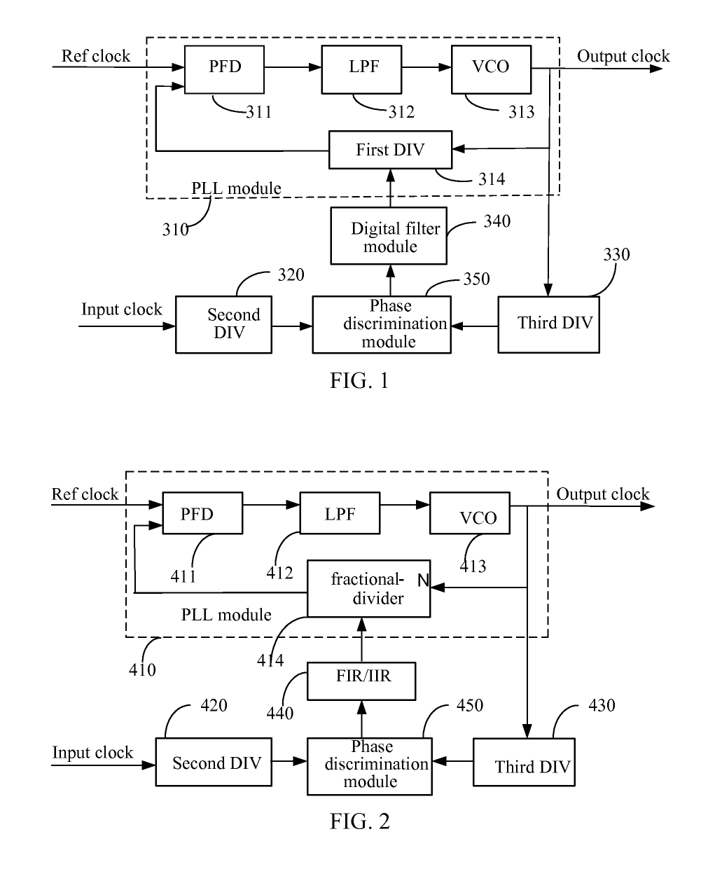

FIG. 1 is a schematic diagram of an apparatus for stabilizing a clock according to a first embodiment of the present invention. Referring to FIG. 1, the apparatus includes a PLL module 310, two frequency dividers (DIVs), i.e., a second DIV 320 and a third DIV 330, a digital filtering module 340, a phase discrimination module 350 connected to the digital filtering module, the second DIV 320, and the third DIV 330. Aref clock is input to the PLL module 310. The PLL module 310 includes a PFD 311, an LPF 312, a VCO 313, and a first DIV 314. The phase discrimination module 350 may be a phase discriminator (PD) or a PFD. It is assumed that the first DIV 314 has a division ratio of K₁, the second DIV 320 has a division ratio of K₂, and the third DIV 330 has a division ratio of K₃. An input clock of the PLL module 310 is a ref clock, which is adapted to decrease the phase noises of an output clock. In consideration of the cost and convenience in realization, the frequency of the ref clock is generally not too high (for example, the ref clock obtained through oscillation usually has a frequency of scores of megahertz). An input clock of the second DIV 320 is an input clock of the apparatus for stabilizing a clock. An input clock of the third DIV 330 is an output feedback clock generated by the apparatus for stabilizing a clock. Herein, the output feedback clock is the output clock of the PLL module. Firstly, frequency division is performed on the input clock and the output feedback clock through the second DIV 320 and the third DIV 330, and then the divided input clock and output feedback clock are input into the phase discrimination module 350, and a phase difference signal for reflecting a phase difference between the input clock and the output feedback clock is generated by the phase discrimination module 350. Then, the digital filtering module 340 applies a low pass filtering on the phase difference signal for reflecting a phase difference between the input clock and the output feedback clock generated by the phase discrimination module 350. Then, a division ratio of the PLL module 310 is adjusted according to the filtered phase difference signal till the phase difference between the input clock and the output feedback clock maintains a stable state, thereby generating a stable output clock. The stable state may include that the phase difference thereof is zero, or the phase difference is not zero, but the output of the phase discrimination module 350 does not change any longer.

As seen from FIG. 1, the apparatus for stabilizing a clock in the embodiment of the present invention has two loops. Once the two loops are stabilized, a stable clock can be output. One loop is an internal loop within the PLL module 310, which maintains stable as long as a phase difference between the two input clocks (the ref clock and a clock obtained after the frequency division of the output feedback clock performed through the first DIV 314) of the PFD 311 is in a stable state. The other loop is a loop for the apparatus for stabilizing a clock, which maintains stable, as long as a phase difference between input clocks (a clock obtained after the frequency division of the input clock performed through the second DIV 320 and a clock obtained after the frequency division of the output feedback clock performed through the third DIV 330) of the phase discrimination module is in a stable state. Once the aforementioned two loops are both stable, the apparatus for stabilizing a clock can generate a stable output clock. Thus, the digital filtering module 340 in the embodiment applies the low pass filtering on the phase difference between the input clock and the output feedback clock, thereby filtering out the high frequency components in the input clock. In addition, a digital filter with an extremely low bandwidth may be provided according to the working principle of a digital filter. Therefore, the LPF 312 in the PLL module 310 is not required to have a low bandwidth, so that the requirements on bandwidth of the LPF 312 in the PLL module 310 are reduced, thereby satisfying a low bandwidth filtering requirements on the input clock, and generating a stable output clock.

In order to further understand the embodiments of the present invention, the aforementioned loops and the conditions for keeping the two loops stable are respectively illustrated below.

Considering the loop formed in the PLL module 310, when the whole circuit is in operation, the frequency of the output clock in this loop is directly controlled by the ref clock and the PLL module 310. If the division ratio of the first DIV 314 is K₁, when the loop is locked, the two input clocks of the PFD 311 should have the same frequency, i e, the f_{ref} satisfying the formula fₒᵤₜ=f_{ref}×K₁.

Considering the other loop formed in the apparatus for stabilizing a clock, in order to lock this loop, the two input clocks of the phase discrimination module 350 should have the same frequency, i.e., the input clock fᵢₙ/K₂ after being performed frequency division by the second DIV 320 and the output feedback clock fₒᵤₜ/K₃ after being performed frequency division by the third DIV 430 have the same frequency, i.e., the fᵢₙ satisfying the formula

$${f}_{out} = {f}_{in} \times \frac{{K}_{3}}{{K}_{2}} .$$

That is to say, in this embodiment, in order to generate a stable clock by the apparatus for stabilizing a clock, the following two formulas are satisfied:

$${f}_{out} = {f}_{ref} \times {K}_{1} , and$$

$${f}_{out} = {f}_{in} \times \frac{{K}_{3}}{{K}_{2}} ,$$

wherein the K₁ is a dynamically changed value, which is determined by the phase difference between the input clock and the output feedback clock. Thus, the division ratio K₁ of the first DIV 312 is adjusted according to the phase difference between the input clock and the output feedback clock, and thus, the two loops can maintain a stable state.

FIG. 2 is a schematic view of an apparatus for stabilizing a clock according to another embodiment of the present invention. Referring to FIG. 2, in this embodiment, the digital filtering module is a finite impulse response (FIR) filter or an infinite impulse response (IIR) filter 440. The first DIV may adopt a fractional-N divider 414, so as to keep the frequency change of the output clock relatively small when the division ratio of the fractional-N divider 414 is adjusted. Both the second DIV 420 and the third DIV 430 may adopt integer-N dividers, so as to simply the frequency dividing circuit. The second DIV 420 also can be omitted according to practical conditions, and the digital signal processing part may directly adopt a digital filter (FIR or IIR). Practically, the PLL module can be designed as an independent PLL module, so that the conventional mature design mode of the fractional-N phase locked loop can be adopted. In order to improve the output clock, a −Σ modulation circuit may be added to the digital filter. The −Σ modulation circuit is a common module in the fractional-N phase locked loop. The other parts are the same as that shown in FIG. 1, and will not be repeatedly described here.

According to the foregoing embodiments of the present invention, two loops exist in the embodiments of the present invention, and the digital filtering part and the phase locked loop PLL module can be designed separately, so that the design is quite simple, the cost is fairly low, and the development cycle is very short.

Optionally, the changing frequency of the first DIV may be designed much (for example, 100 times) greater than the loop bandwidth of the PLL module. Thus, each time after the first DIV is changed, the PLL module could get in a locked state before the first DIV is changed again, and the time required by the locking step merely occupies a small portion of the changing cycle of the first DIV Therefore, the analysis about the stability of the loop of the PLL module is not influenced by the other loop. Meanwhile, the influence on the analysis about the stability of a digital loop caused by the relocking process of the PLL module can also be neglected.

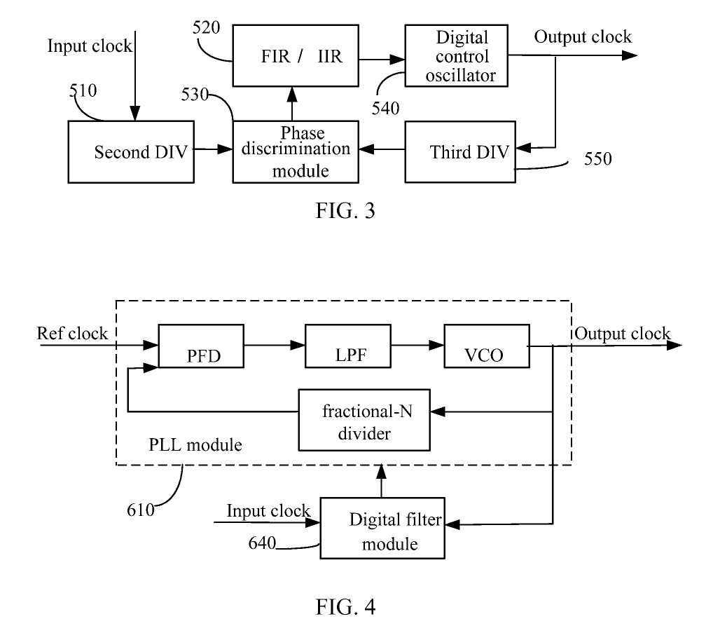

FIG. 3 is a schematic view of an apparatus for stabilizing a clock according to still another embodiment of the present invention. Referring to FIG. 3, in this embodiment, the PLL module is a digital control oscillator 540, i.e., a functional module in which the frequency of the output clock is directly proportional to the input number. Therefore, the apparatus in this embodiment can be designed through a conventional mature digital signal processing theory, and includes a second DIV 510, an FIR/IIR 520, a phase discrimination module 530, a digital control oscillator 540, and a third DIV 550.

FIG. 4 is a schematic view of an apparatus for stabilizing a clock according to still another embodiment of the present invention. Referring to FIG. 4, in this embodiment, the output clock is adopted as a work clock of the digital filtering module 640. In the design of the digital integrated circuit, generally, a work clock is needed, and especially for the design of the synchronous digital integrated circuit, the work clock is indispensable. Generally, the work clock is required to have a stable frequency, and the frequency must be at least twice higher than that of any signal to be processed. In the above embodiments, the work clock of the digital filter can use the ref clock (or a frequency multiplier clock of the ref clock). In order to omit the frequency multiplier circuit of the ref clock, the embodiments of the present invention may directly take the output clock as the work clock for the digital circuits.

In an embodiment of the present invention further provides a method for stabilizing a clock, which includes the steps: obtaining a signal for reflecting a phase difference between an input clock and an output feedback clock according to the input clock and the output feedback clock, and applying a low pass filtering on the signal for reflecting the phase difference between the input clock and the output feedback clock; and adjusting a division ratio of a phase locked loop (PLL) module according to the filtered signal, so as to influence an output clock generated by the PLL; and updating the output feedback clock to the output clock. In this way, the signal for reflecting the phase difference between the input clock and the output feedback clock varies according to the change of the output clock. Thus, once the phase difference between the input clock and the output feedback clock maintains a stable state, the PLL module generates a stable output clock. Therefore, the requirements on the bandwidth of the LPF in the PLL module are reduced, thereby the low bandwidth filtering requirements on the input clock is satisfied, and a stable output clock is generated.

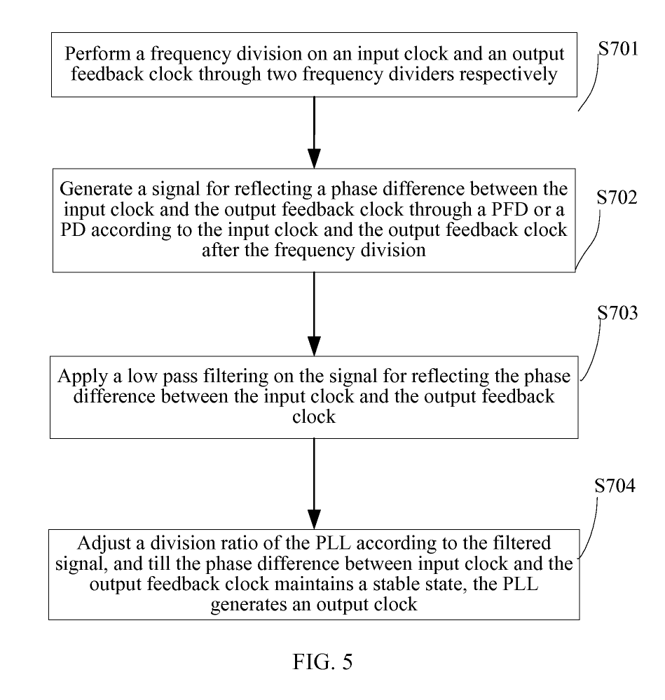

FIG. 5 is a flow chart of a method for stabilizing a clock according to the embodiment of the present invention. Referring to FIG. 5, the method includes the following steps.

In Step S701, frequency divisions are respectively performed on an input clock and an output feedback clock through two frequency dividers.

In Step S702, a signal for reflecting a phase difference between the input clock and the output feedback clock is generated through a PFD or a PD according to the input clock and the output feedback clock after the frequency division.

In Step S703, perform low pass filtering on the signal for reflecting the phase difference between the input clock and the output feedback clock. Preferably, a digital filter is adapted to apply the low pass filtering on the signal for reflecting the phase difference between the input clock and the output feedback clock, thereby filtering off the high frequency components in the input clock. Furthermore, a digital filter with an extremely low bandwidth can be provided according to the working principle of the digital filter. Thus, the LPF in the PLL module is not required to have a low bandwidth.

In Step S704, a division ratio of the PLL module is adjusted according to the filtered signal, and till the phase difference between the input clock and the output feedback clock maintains a stable state, the PLL module generates a stable output clock.

In the embodiments of the present invention, the low pass filtering is applied on the phase difference signal between the input clock and the output feedback clock through the digital filter, thereby reducing the requirements on the bandwidth of the LPF in the PLL module. In addition, the division ratio of the PLL module is adjusted according to the filtered phase difference between the input clock and the output feedback clock, so that the output clock is associated with the input clock.

Through the above descriptions of the embodiments, those skilled in the art can clearly understand that, the present invention is realized through combining software with a necessary universal hardware platform, which definitely can be realized through hardware, but in most cases, the former manner is preferred. Based on such understanding, the technical solutions of the present invention or parts of the technical solutions of the present invention making contributions to the related art are substantially presented in the form of a software product. The obtained software product is stored in a storage medium, which includes a plurality of instructions for enabling computer equipment (such as a personal computer, a server, or a network equipment) to execute the method according to the embodiment of the present invention.

The above embodiments are merely intended to describe the technical solutions of the present invention, but not to limit the scope of present invention. It will be apparent to those skilled in the art that various modifications and variations can be made to the structure of the present invention without departing from the scope or spirit of the invention.

1. An apparatus for stabilizing a clock, comprising a phase locked loop (PLL) module (310, 410, 540, 610), a phase discrimination module (350, 450, 530) and a digital filtering module (340, 440, 520, 640), wherein
the PLL module (310, 410, 540, 610) is configured to receive a filtered phase difference signal from the digital filtering module (340, 440, 520, 640) and output an output clock;
the phase discrimination module (350, 450, 530) is configured to receive an output feedback clock of the output clock and an input clock, and generate a phase difference signal reflecting a phase difference between the output feedback clock and the input clock;
the digital filtering module (340, 440, 520, 640) is configured to receive the phase difference signal from the phase discrimination module (350, 450, 530), and generate the filtered phase difference signal after filtering the phase difference signal, then send the filtered phase difference signal to the PLL module (310, 410, 540, 610);
wherein a division ratio of the PLL module (310, 410, 540, 610) is adjusted according to the filtered phase difference signal till the phase difference between the input clock and the output feedback clock maintains a stable state.

2. The apparatus for stabilizing a clock according to claim 1, wherein the PLL module (310, 410, 540, 610) is further configured to receive a ref clock, and the ref clock is adapted to decrease the phase noises of the output clock.

3. The apparatus for stabilizing a clock according to claim 1, wherein a changing frequency of a frequency divider of the PLL module is much greater than a loop bandwidth of the PLL module.

4. The apparatus for stabilizing a clock according to claim 1, wherein the apparatus further comprises: two frequency dividers connected to the phase discrimination module (350, 450, 530); wherein
one of the frequency dividers (320) is configured to divide the frequency of the input clock, then send the input clock to the phase discrimination module (350, 450, 530);
the other of the frequency dividers (320) is configured to divide the frequency of the output feedback clock, then send the output feedback clock to the phase discrimination module (350, 450, 530).

5. The apparatus for stabilizing a clock according to claim 1, wherein the phase discrimination module (350, 450, 530) is a phase discriminator or a phase and frequency detector.

6. The apparatus for stabilizing a clock according to claim 1, wherein the digital filtering module (340, 440, 520, 640) is a digital signal processor, a finite impulse response filter or an infinite impulse response filter.

7. The apparatus for stabilizing a clock according to claim 1, wherein the PLL module (310, 410, 540, 610) comprises a digital control oscillator, and the frequency of the output clock is proportional to an input number in the digital control oscillator.

8. An apparatus for stabilizing a clock, comprising a phase locked loop (PLL) module (310, 410, 540, 610) and a digital filtering module (340, 440, 520, 640), wherein
the PLL module (310, 410, 540, 610) is configured to receive a ref clock and a signal from the digital filtering module (340, 440, 520, 640), and output an output clock, wherein the ref clock is adapted to decrease the phase noises of the output clock;
the digital filtering module (340, 440, 520, 640) is configured to receive an output feedback clock of the output clock and an input clock, and generate a signal, wherein a division ratio of the PLL module (310, 410, 540, 610) is adjusted according to the signal till the phase difference between the input clock and the output feedback clock maintains a stable state.

9. A method for stabilizing a clock, comprising:
obtaining a signal for reflecting a phase difference between an input clock and an output feedback clock according to the input clock and the output feedback clock of the output clock, wherein an output clock is taken as the output feedback clock;
generating a filtered signal after filtering the signal; and
adjusting a division ratio of a phase locked loop (PLL) module according to the filtered signal to influence the output clock generated by the PLL module.

10. The method for stabilizing a clock according to claim 8, wherein the generating a filtered signal after filtering the signal comprises:
generating the filtered signal after applying a low pass filtering on the signal.

11. The method for stabilizing a clock according to claim 8, wherein the obtaining a signal for reflecting a phase difference between an input clock and an output feedback clock, comprises:
performing frequency divisions respectively on the input clock and the output feedback clock.

12. The method for stabilizing a clock according to claim 8, wherein the obtaining a signal for reflecting a phase difference between an input clock and an output feedback clock comprises:
obtaining, by a phase discriminator or a phase and frequency detector, the signal for reflecting the phase difference between the input clock and the output feedback clock.
